(19) United States
(12) Patent Application Publication
(10) Pub. No.: US 2018/0337321 A1
(43) Pub. Date: Nov. 22, 2018

(54) REPLICATED THERMOELECTRIC DEVICES

(71) Applicant: Sheetak Inc., Austin, TX (US)

(72) Inventor: Uttam GHOSHAL, Austin, TX (US)

(73) Assignee: Sheetak Inc.

(21) Appl. No.: 15/986,917

(22) Filed: May 23, 2018

Related U.S. Application Data
(63) Continuation of application No. 14/704,569, filed on May 5, 2015, now abandoned.
(60) Provisional application No. 61/991,340, filed on May 9, 2014.

(51) Int. Cl. H01L 35/34; H01L 35/16; H01L 35/32; H01L 35/18

(52) U.S. Cl. CPC H01L 35/34; H01L 35/18; H01L 35/32; H01L 35/16

(57) ABSTRACT

A method of creating a replicated thermoelectric device includes preparing a single thermoelectric device for division. The single thermoelectric device including a plurality of thermoelements positioned between a first substrate and a second substrate. The method further includes dividing the single thermoelectric device to form a replicated thermoelectric device such that the cooling power of the replicated thermoelectric cooling device is substantially equal to twice a cooling power of the single thermoelectric device.

### CROSS-REFERENCE TO RELATED APPLICATIONS

The application is a continuation of U.S. non-provisional application Ser. No. 14/704,569, filed May 5, 2015 and claims the benefits of priority from U.S. Provisional Application No. 61/991,340, filed May 9, 2014, which are incorporated herein by reference herein in their entireties.

### TECHNICAL FIELD

The present invention relates to thermoelectric elements and thermoelectric devices, and cost effective methods for producing the thermoelectric elements and thermoelectric devices.

### BACKGROUND

Thermoelectric devices (TEDs) are solid-state devices that produce electrical energy when subjected to a temperature gradient, and produce a temperature gradient when subjected to an electric current. The conversion of a temperature difference into electrical energy is due to the Seebeck effect, and the conversion of electrical energy into a temperature gradient is due to an inverse reciprocal effect known as the Peltier effect. A thermoelectric cooling device (also known as a Peltier device) is a TED which transfers heat from one location to another when a current is directed through the device, and a thermoelectric generator is a TED which generates an electric current when a temperature gradient is applied across the device. Thermoelectric devices (TEDs) have a tremendous potential in providing eco-friendly solutions to energy and cooling needs.

A TED includes one or more thermoelectric elements (or thermoelements) connected electrically in series and thermally in parallel between two thermally conductive and electrically insulating substrates. Depending upon the type of energy input into the device, the device functions as a cooling device or a power generating device. The thermoelements are formed of materials which exhibit a strong thermoelectric effect (thermoelectric materials). Typically, commercially available TEDs have a low efficiency (cooling power, power generation efficiency, etc.) due to their poor material properties and large form factors. The efficiency of a TED is directly proportional to the Seebeck coefficient of the thermoelement and inversely proportional to the thickness of the thermoelement between the substrates (transport length).

In conventional TEDs, multiple thermoelements formed by dicing (cutting) a wafer of a thermoelectric material is attached (brazed, soldered, etc.) between two metallized substrates. Due to practical limitations, the thickness of these wafers is typically greater than or equal to 1 mm. Therefore, the transport length of the TEDs prepared using these thermoelements exceed 1 mm which decreases their efficiency.

The devices, systems, and methods of the current disclosure may alleviate some of the deficiencies discussed above.

### SUMMARY

In one aspect, a method of creating a replicated thermoelectric device from a starting thermoelectric device is disclosed. The starting thermoelectric device may include a plurality of thermoelements positioned between a first substrate and a second substrate. The method may include cutting the starting thermoelectric device along a plane passing through the plurality of thermoelements to create (i) a first part with a first portion of the plurality of thermoelements and (ii) a second part with a second portion of the plurality of thermoelements. The method may further include attaching a third substrate to the first part to create a replicated thermoelectric device. Wherein, the third substrate is attached such that the first portion of the plurality of thermoelements is positioned between the first substrate and the third substrate.

Additionally or alternatively, in some aspects, the replicated thermoelectric device may be a first replicated thermoelectric device, and the method may further include attaching a fourth substrate to the second part to create a second replicated thermoelectric device, wherein the fourth substrate is attached such that the second portion of the plurality of thermoelements is positioned between the second substrate and the fourth substrate; attaching the third substrate to the first part may include soldering the third substrate to a top surface of the first portion of the plurality of thermoelements; the method may further include depositing a barrier material on a top surface of the first portion of the plurality of thermoelements prior to attaching the third substrate; attaching the third substrate may include attaching the third substrate such that the first portion of the plurality of thermoelements are connected electrically in series; cutting the starting thermoelectric device may include cutting the starting thermoelectric device along a plane substantially parallel to the first substrate; cutting the starting thermoelectric device may include cutting the starting thermoelectric device along a plane positioned substantially midway between the first substrate and the second substrate; the first substrate and the second substrate may be Aluminum Nitride substrates with metallic interconnects thereon; the plurality of thermoelements may be connected between the metallic interconnects of the first and second substrates; and the third substrate may be an Aluminum Nitride substrate with metallic interconnects thereon, and wherein attaching the third substrate to the first part may include attaching the first portion of the plurality of thermoelements to metallic interconnects of the third substrate.

In another aspect, a method of creating a replicated thermoelectric device from a single thermoelectric device is disclosed. The single thermoelectric device may include a plurality of thermoelements positioned between a first substrate and a second substrate. The method may include dividing the single thermoelectric device to form a replicated thermoelectric device having a cooling power substantially equal to twice a cooling power of the single thermoelectric device.

Additionally or alternatively, in some aspects, the dividing may include cutting the single thermoelectric device along a plane passing through the plurality of thermoelements to create two parts; the dividing may further include soldering a substrate to each of the two parts to form two replicated thermoelectric cooling devices; and the cutting may include cutting the plurality of thermoelements along substantially a midpoint between the first and the second substrates; the plurality of thermoelements may include one or more p-type thermoelements and one or more n-type thermoelements.

In yet another aspect, a replicated thermoelectric device may include a first ceramic substrate and a second ceramic substrate. The replicated thermoelectric device may include a plurality of thermoelements positioned between the first and the second ceramic substrates. A thickness of the thermoelements in a direction normal to the first and second ceramic substrates may be less than or equal to 0.03 mm.

Additionally or alternatively, in some aspects, the plurality of thermoelements may include one or more p-type thermoelements and one or more n-type thermoelements; the plurality of thermoelements may include Bi_{0.5}Sb_{1.5}Te₃; the first and second ceramic substrates may include Aluminum Nitride; and at least one of the thermoelements may include multiple layers of a thermoelectric material and a substrate stacked one on top of another.

### BRIEF DESCRIPTION OF THE DRAWINGS

The preferred embodiments of the present invention will hereinafter be described in conjunction with the appended drawings that are provided to illustrate, and not to limit the invention, wherein like designations denote like elements, and in which:

FIG. 1 illustrates a cross-sectional view of an exemplary embodiment of a thermoelectric foil;

FIG. 2 illustrates a cross-sectional view of an exemplary embodiment of a multi-layer thermoelectric foil;

FIG. 3A is a schematic illustration of an exemplary method of creating the multi-layer thermoelectric foil of FIG. 2 by stacking the thermoelectric foil of FIG. 1;

FIG. 3B is a schematic illustration of an exemplary method of creating the multi-layer thermoelectric foil of FIG. 2 by folding the thermoelectric foil of FIG. 1;

FIG. 3C is a schematic illustration of another exemplary method of creating the multi-layer thermoelectric foil of FIG. 2 by folding the thermoelectric foil of FIG. 1;

FIG. 3D is a schematic illustration of an exemplary method of creating the multi-layer thermoelectric foil of FIG. 2 by rolling the thermoelectric foil of FIG. 1;

FIG. 4A illustrates an exemplary method of folding the thermoelectric foil of FIG. 1;

FIG. 4B illustrates another exemplary method of folding the thermoelectric foil of FIG. 1;

FIG. 5 illustrates a method of creating thermoelements from the thermoelectric foil of FIG. 2;

FIG. 6 is a flow chart that illustrates an exemplary method of creating thermoelements from the thermoelectric foil of FIG. 1;

FIG. 7A is a cross-sectional view of an exemplary embodiment of a thermoelectric device;

FIGS. 7B-7E are cross-sectional schematic views illustrating an exemplary method of creating two replicated thermoelectric devices from the thermoelectric device of FIG. 7A; and

FIG. 8 is a flow chart that illustrates an exemplary method of creating two replicated thermoelectric devices from a single thermoelectric device.

### DETAILED DESCRIPTION OF THE INVENTION

Although the current disclosure is equally applicable to all types of TEDs (thermoelectric cooling devices and thermoelectric power generation devices), for the sake of brevity, a thermoelectric cooling device is described below. Before describing exemplary embodiments in detail, it should be noted that only those details that are relevant for an understanding of the current disclosure have been illustrated and described herein.

### Thermoelements

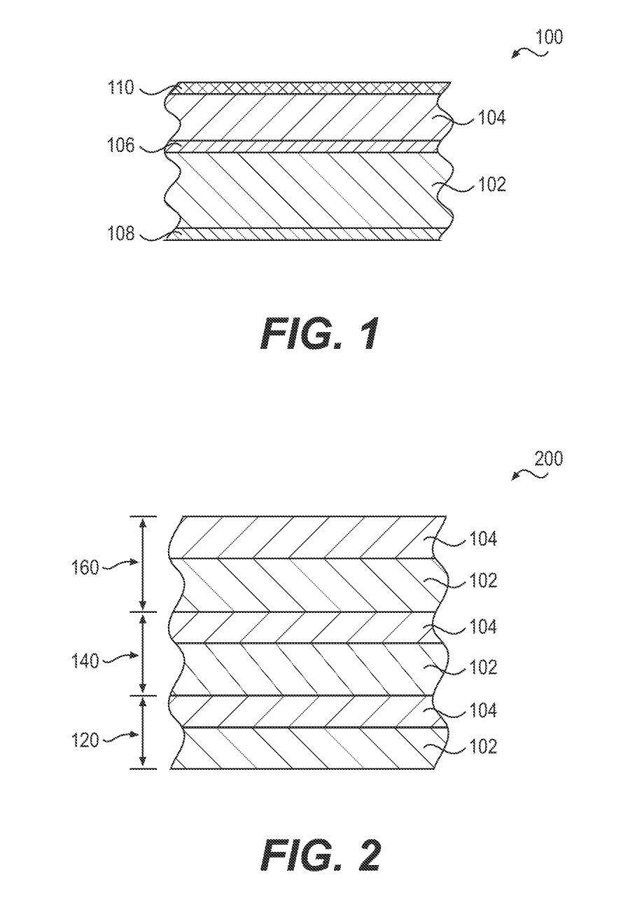

FIG. 1 illustrates a cross-sectional view of a thermoelectric foil 100. Thermoelectric foil 100 includes a substrate 102 with a thermoelectric film 104 deposited thereon. Thermoelectric film 104 may include an n-type thermoelectric film or a p-type thermoelectric film. As is known in the art, an n-type material is a material that has excess electrons and a p-type material is a material that has excess holes. In some embodiments, a p-type thermoelectric film 104 may include a Bismuth Antimony Telluride alloy (Bi₂₋ₓSbₓTe₃) and an n-type thermoelectric film 104 may include a Bismuth Tellurium Selenide alloy (Bi₂Te_{3-y}Se_{y}), where x and y vary between about 1.4-1.6 and about 0.1-0.3 respectively. When a current flows through thermoelectric foil 100, heat is extracted from substrate 102 towards the thermoelectric film 104. Although one layer of a film 104 on a substrate 102 is illustrated in FIG. 1, in general, thermoelectric foil 100 may include any number of thermoelectric films provided thereon.

In some embodiments, substrate 102 may be a semiconductor substrate made of a material such as Silicon (Si) or Gallium Arsenide (GaAs). In other embodiments, substrate 102 may be a metal substrate (for example, Aluminum (Al), Tungsten (W), Nickel (Ni), Molybdenum (Mo), Copper (Cu), etc.). A metal substrate may facilitate the dissipation of heat. In some exemplary embodiments, a thin Aluminum substrate having a thickness between about 5-10 micrometers (or microns, 1 micron=0.039 mils=3.94×10⁻⁵ inches) may be used. Use of a thin Aluminum substrates may make reduce the cost of thermoelectric foil 100. However, in general, substrate 102 may have any thickness (for example, between about 1-50 microns).

Substrate 102 may include a first layer 106 on its first side (for example, the top side). In some embodiments, the first layer 106 may serve as a wetting layer for the thermoelectric film 104. First layer 106 may improve the adhesion of film 104 to the substrate 102, thereby reduce contact resistance. First layer 106 may include materials such as, but are not limited to, Titanium (Ti), Titanium Tungsten (TiW), Nickel (Ni), Platinum (Pt), Tantalum (Ta), and TaN (Tantalum Nitride).

In some embodiments, a second layer 108 may be provided on a second side (for example, the bottom) of substrate 102. Second layer 108 may protect the substrate 102 from environmental factors. In embodiments where substrate 102 is made of a metal, second layer 108 may protect the substrate 102 from oxidization. Second layer 108 may include materials such as, but are not limited to, TiW, Ni, Pt and Gold (Au). In some embodiments, second layer 108 may also act as a wetting layer for a solder which may be used to solder the substrate to an interconnect of a thermoelectric device.

In some embodiments, thermoelectric film 104 may include a third layer 110 on its surface. Third layer 110 may prevent the thermal diffusion of materials into the thermoelectric film 104. Third layer 110 may include materials such as, but are not limited to, Aluminum (Al), Platinum (Pt), Nickel (Ni), Tantalum (Ta), Tantalum Nitride (TaN), Tungsten (W) and Titanium Tungsten (TiW). First layer 106, second layer 108, and third layer 110 may be provided on the foil 100 by any known means. In some embodiments, one or more of first layer 106, second layer 108, and third layer 110 may include multiple layers of different materials. For instance, in some embodiments, first layer 106 and second layer 108 may include both a layer of TiW and a layer of Al.

Exemplary embodiments of thermoelectric foil 100 are listed in Table I below. The numbers in brackets in column 1 of Table I correspond to reference numbers in FIG. 1

TABLE I
Material compositions in exemplary embodiments
of thermoelectric foils.

| | Exemplary embodiment | | | |
|---|---|---|---|---|
| Layer | A | B | C | D |
| First layer | TiW/Al | TiW/Pt | TiW/Al | Al |
| (106) | | | | |
| Second layer | TiW/Al | TiW/Pt | TiW/Al | Al |
| (108) | | | | |
| Thermo- | Bi_{0.5}Sb_{1.5}Te₃ | Bi_{0.5}Sb_{1.5}Te₃ | Bi_{0.5}Sb_{1.5}Te₃ | Bi_{0.5}Sb_{1.5}Te₃ |
| electric film | | | | |
| (104) | | | | |
| Third layer | TiW | Pt/TiW | Ta/TaN | W |
| (110) | | | | |
| Substrate | Al | Al | Cu | W |
| (102) | | | | |

That is, in exemplary embodiment A of Table I, a layer of TiW and Al is deposited as a barrier layer on both sides of an Al substrate, and a Bi_{0.5}Sb_{1.5}Te₃ thermoelectric film is deposited on one side of the substrate. A TiW barrier layer is then deposited on the surface of the thermoelectric film. In some embodiments, the thermoelectric foil 100 may be a layered structure of Al/TiW—Bi_{0.5}Sb_{1.5}Te₃—Al—AgSbPb₁₈Te₂₀—TiW/Al, or Al/TiW—Bi_{0.5}Sb_{1.5}Te₃—Al—Bi_{0.5}Sb_{1.5}Te₃—TiW/Al.

Thermoelectric foil 100 may be formed by any known process. In some embodiments, thermoelectric film 104 (and first, second, and third layers 106, 108, 110 if any) may be deposited on the substrate 102. Any deposition process (physical vapor deposition, chemical vapor deposition, etc.) known in the art may be used to deposit the film 104 and the different layers. In some embodiments, sputtering may be used to deposit film 104 on the substrate 102. Since deposition processes used to deposit thin films are known in the art, they are not discussed herein.

The thermoelectric film 104, and the first, second, and third layers 106, 108, 110 may have any thickness. In general, the thermoelectric film 104 thickness may be between about 1-50 microns. In some embodiments, the film 104 thickness may be between 5-10 microns. The thickness of the second layer 108 may vary between about 10-30 microns, and the thickness of the first and third layers 106, 110 may vary between about 0.1-1 microns. In some embodiments, the thickness of the second layer 108 may vary between about 15-20 microns.

FIG. 2 illustrates another embodiment of a thermoelectric foil 200 of the current disclosure. As illustrated in FIG. 2, thermoelectric foil 200 may include a plurality of stacked layers 120, 140, 160 of substrates 102 and thermoelectric films 104. Although not illustrated in FIG. 2, thermoelectric foil 200 may also include the first, second, and third layers 106, 108, 110 discussed with reference to FIG. 1. Further, although only three layers 120, 140, 160 are illustrated in FIG. 2, in general, thermoelectric foil 200 may include any number of layers. The thicknesses and the material compositions of the substrates and films in the different layers 120, 140, 160 may be the same or may be different. Cooling power of thermoelectric foil 200 may be the sum of the cooling power of each individual layer 120, 140, 160. Thus, thermoelectric foil 200 with a plurality of layers 120, 140, 160 of substrates 102 and thermoelectric films 104 may have a higher cooling power than thermoelectric foil 100 having a single layer of substrate 102 and thermoelectric film 104.

In general, thermoelectric foil 200 may be produced by any method. In some embodiments, alternate layers of substrates 102 and thermoelectric films 104 may be formed by deposition. However, deposition (for example, sputtering) is a relatively expensive and time consuming process. Therefore, producing thermoelectric foil 200 by depositing each individual thermoelectric film 104 and substrate 102 layer may be prohibitively expensive and time consuming.

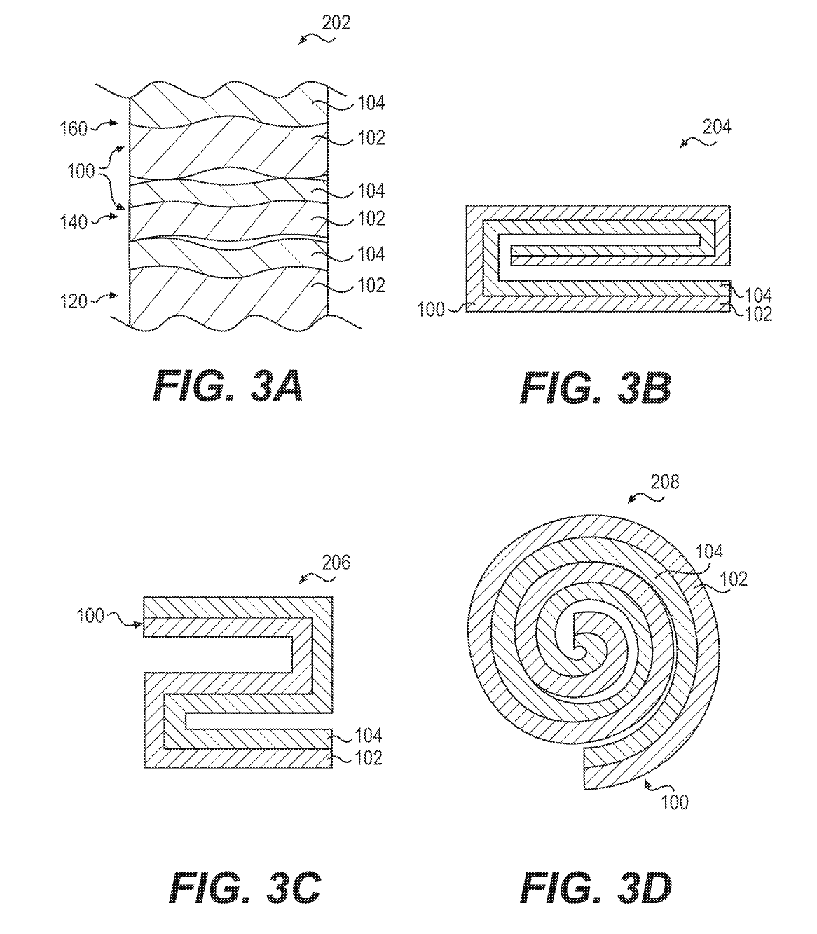

FIGS. 3A-3D illustrate multi-layer thermoelectric foils 202, 204, 206, and 208 formed in accordance with exemplary embodiments of the current disclosure. Thermoelectric foils 202, 204, 206, and 208 include multiple layers of thermoelectric films 104 and substrates 102 and may be created using thermoelectric foil 100 of FIG. 1. In the embodiment of FIG. 3A, thermoelectric foil 100 (of FIG. 1) may be diced or cut into multiple pieces, and these multiple pieces arranged one on top of another to create a stacked layer of foils. This stacked layer may then be consolidated or joined (for example, by applying pressure and/or heat, etc.) to create a multi-layer thermoelectric foil 202.

In the embodiment of FIG. 3B, thermoelectric foil 100 of FIG. 1 may be folded one or more times to form multiple layers of substrates 102 and thermoelectric films 104 stacked one on top of another. The stacked film may then be consolidated to form thermoelectric foil 204. Foil 100 may be folded in any direction (clockwise or counterclockwise). In the embodiment of FIG. 3B, foil 204 is formed by repeatedly folding foil 100 in the same direction (for example, clockwise or counter clockwise). FIG. 3C illustrates a thermoelectric foil 206 formed by folding foil 100 in a zigzag manner. That is, foil 100 is first folded in the clockwise direction and then in the counterclockwise direction to form a stacked layer. In some embodiments, a multi-layer thermoelectric film foil may be formed by rolling foil 100. FIG. 3D illustrates an embodiment in which thermoelectric film foil 100 is rolled to form a roll of thermoelectric foil 208. In the embodiments of FIGS. 3A-3D, any number of layers of films 104 and substrates 102 may be stacked together to form alternating layers of substrates and thermoelectric films. It should be noted that, the thickness of the substrates 102 and the films 104 of some or all of the layers formed in the embodiments of foils 204 and 206 (FIGS. 3B, 3C) will be more than those formed in foils 202 and 208. In some embodiments, several hundred layers of thermoelectric films 104 and substrates 102 may be stacked together to form foils 202, 204, 206, and 208. In some embodiments, the number of layers may be about ten.

Although a single-layer thermoelectric foil 100 is described as being stacked, folded, or rolled to create a multi-layer thermoelectric foil 200, this is not a limitation. Any known process may be used to create a multi-layer thermoelectric foil 200 using a single layer thermoelectric foil 100. It is also contemplated that, in some embodiments, a multi-layer thermoelectric foil may be stacked, folded, or rolled to create a stacked assembly that includes even more layers. Thermoelectric foils 202, 204, 206, 208 have multiple layers of thermoelectric films 104 and substrates 102, and therefore, a higher cooling density.

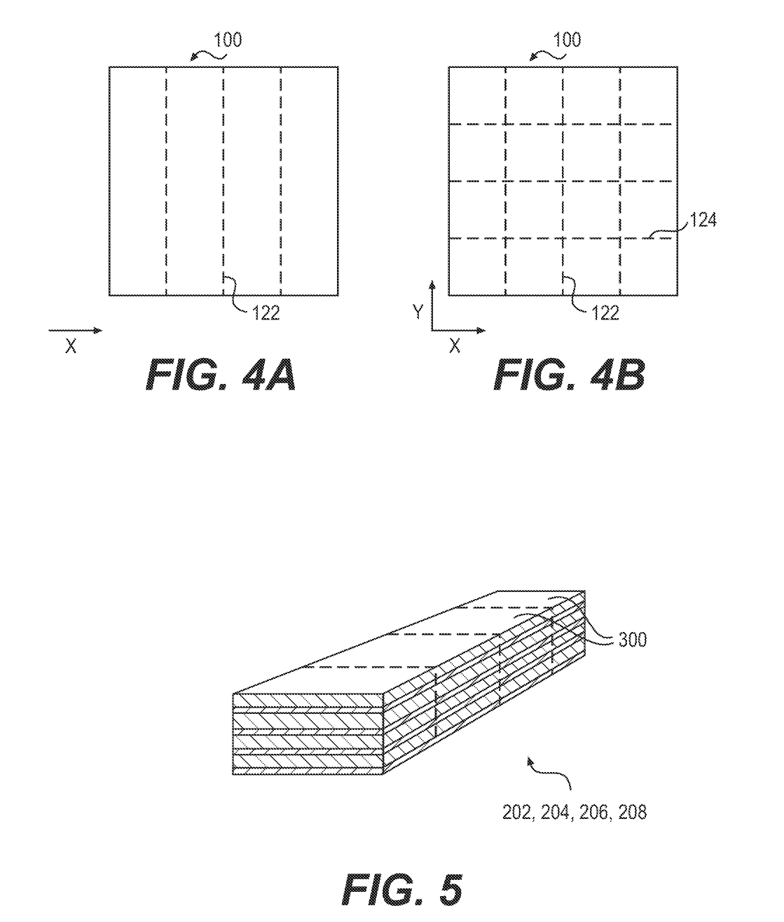

As explained above, thermoelectric foil 100 may be folded or rolled in any direction. In some embodiments, as illustrated in FIG. 4A, thermoelectric foil 100 may be folded along a single axis (x-axis in FIG. 4A). That is, foil 100 may be successively folded along vertical lines 122 of FIG. 4A to create a multi-layer thermoelectric foil. In some embodiments, as illustrated in FIG. 4B, thermoelectric foil 100 may be folded along orthogonal axes (x and y). That is, foil 100 may be folded alternatively along horizontal and vertical lines 124, 122 into successively smaller squares or rectangles to create a multi-layer thermoelectric foil 200. After a multi-layer thermoelectric foil 202, 204, 206, 208 is formed by stacking (FIG. 3A), folding (FIGS. 3B and 3C), or rolling (FIG. 3D), the multiple layers may be consolidated together by applying pressure and/or heat, or by other means (ultrasonic bonding, conductive adhesives, etc.). Consolidating the multiple layers together may remove entrapped air bubbles from between the layers and join the multiple layers together. Thermoelements 300 of a desired shape may then be formed by dicing the consolidated multi-layer thermoelectric foil 200.

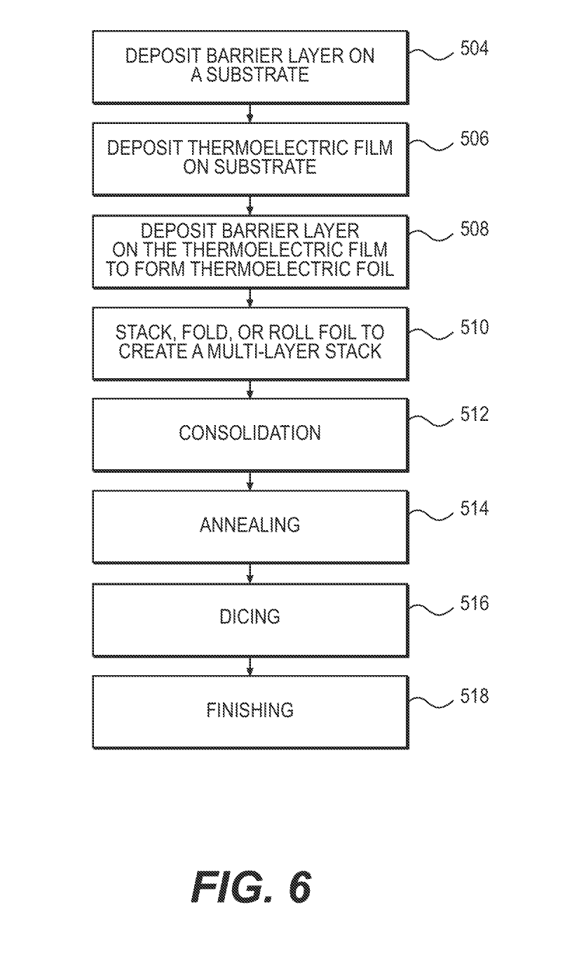

FIG. 6 illustrates a flow chart describing an exemplary method of creating thermoelement 300. Reference will also be made to FIG. 1 in the description below. The method utilizes a metal substrate 102 having a thickness of about 5-10 micrometers. At step 504, a barrier layer (e.g. third layer 106 and second layer 108) is deposited on opposite sides of the metal substrate using sputtering or another suitable process. At step 506, a thermoelectric film 104 is deposited on one side of the metal substrate by sputtering or another suitable process. The thermoelectric film 104 may be a p-type thermoelectric film or an n-type thermoelectric film. At step 508, a second barrier layer (first layer 110) is deposited on the thermoelectric film 104 to form a thermoelectric foil. The second barrier layer may prevent oxidation of the deposited thermoelectric film.

In some embodiments, steps 504, 506, and 508 of FIG. 6 may be eliminated and a previously formed thermoelectric film foil 100 may be selected and used. At step 510, the thermoelectric foil is stacked, folded, or rolled to create a multi-layer thermoelectric foil as described with reference to FIGS. 3A-4B. At step 512, the multi-layer thermoelectric foil is consolidated by applying heat and pressure or by ultrasonic consolidation. In ultrasonic consolidation, high-frequency (typically 20,000 hertz) ultrasonic vibrations are locally applied to the multi-layer thermoelectric foil, held together under pressure, to create a solid-state weld between the different layers. At step 514, the thermoelectric foil is annealed. Consolidating and annealing the thermoelectric foil removes air bubbles, fills any gaps between the different layers of the multi-layer foil, and ensures good thermal and electric contact between the layers. Further, annealing the thermoelectric foil enhances its Seebeck coefficient.

At step 516, the thermoelectric foil is diced to form multiple thermoelements 300. Further, at step 518, the thermoelements are finished, e.g. by acid etching using nitric acid or phosphoric acid. The step of finishing removes any remaining side burrs in the thermoelements 300. Although sputtering is described as being used to deposit the barrier layers and the thermoelectric film in the exemplary method above, as explained previously, any suitable process may be used to deposit these layers.

### Thermoelectric Device (TED)

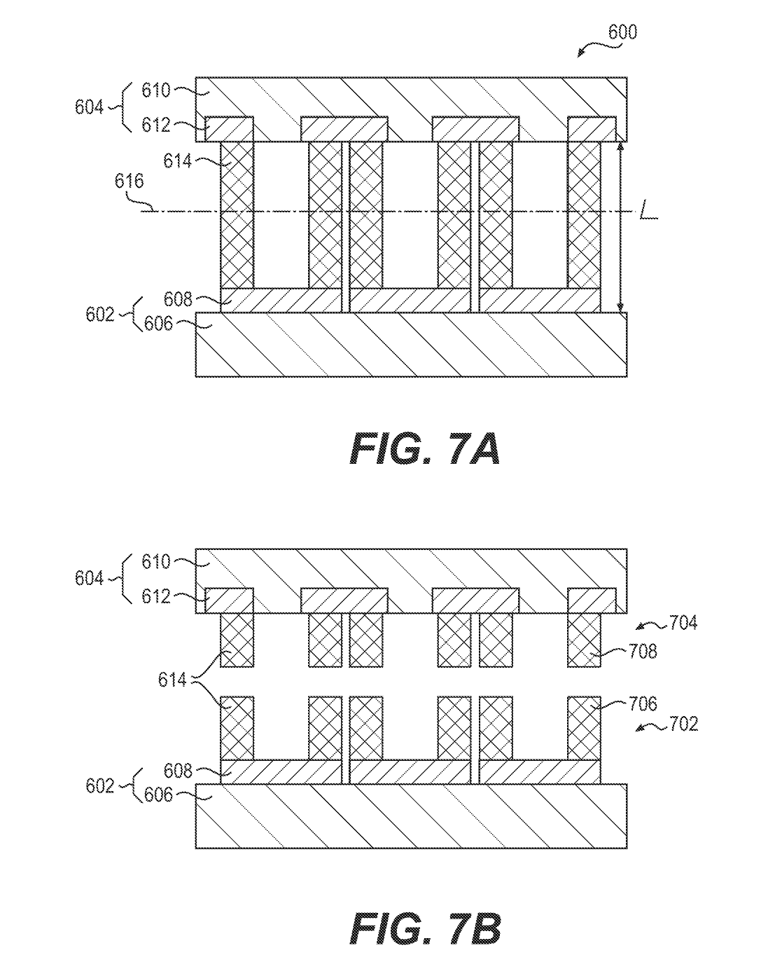

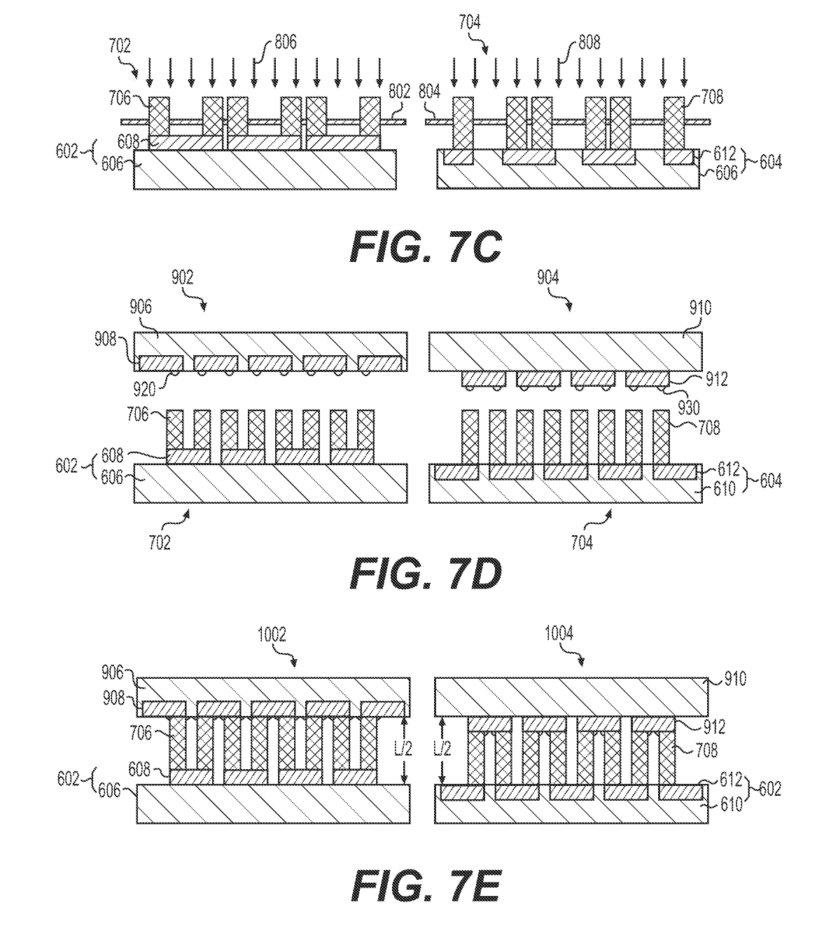

FIG. 7A illustrates a cross-sectional side view of an exemplary TED 600. TED 600 may include one or more thermoelements provided between a first part 602 and a second part 604. First part 602 may include a first layer 606 made of a material with a high thermal conductivity and a low electrical conductivity. In some embodiments, first layer 606 may include a ceramic substrate such as, for example, Aluminum Nitride (AlN). First part 602 also includes a second layer 608, which is a metallic interconnect with a high thermal and electrical conductivity. The second layer 608 may connect the first layer 606 to one or more thermoelements. Typical examples of interconnect materials include, but are not limited to, copper, nickel and aluminum.

Like first part 602, second part 604 includes a third layer 610 and a fourth layer 612. Third layer 610 has a similar function as first layer 606, and is made of a material with a high thermal conductivity and a low electrical conductivity. In some embodiments, third layer 610 may include a ceramic substrate (for example, an aluminum nitride substrate) or a metal-core printed circuit board. Further, fourth layer 612 may include a metallic interconnect similar to second layer 608, and may provide electrical connection between the one or more thermoelements. For efficient heat transfer to layer 610, fourth layer 612 may include a material with a high thermal conductivity. Typical examples of such materials include, but are not limited to, Copper, Nickel and Aluminum.

One or more thermoelements 614 may be provided between first part 602 and second part 604. These thermoelements 614 may be attached to the first and second parts 602, 604 by any means (for e.g., brazing, soldering, etc.) Thermoelement 614 includes either an n-type thermoelement or a p-type thermoelement. In some embodiments, thermoelements 300 created using the process described in FIG. 6 may be used as thermoelement 614 of FIG. 7A. In such embodiments, the thermoelements 300 may be positioned between the first and second parts 602, 604 such that the multiple layers 120, 140, 160 (see FIG. 2) are oriented substantially parallel to the first and second parts 602, 604. In some embodiments, thermoelement 614 may be a conventional thermoelement made by dicing a wafer of a bulk thermoelectric material. In some embodiments, thermoelement 614 may have a composition close to a pseudo-binary system such as Bismuth Antimony Telluride Bi₂₋ₓSbₓTe₃ for the p-type thermoelement, and Bismuth Tellurium Selenide Bi₂Te_{3-y}Se_{y} for the n-type thermoelement, where x varies from about 1.4-1.6 and y varies from about 0.1-0.3. In some embodiments, thermoelement 614 may include a semiconductor substrate (for example, Silicon or Gallium Arsenide) with a deposited (for example, by sputtering) or a grown layer (for example, by molecular beam epitaxy (MBE)) of thermoelectric film.

When a current flows through thermoelement 614, heat is extracted from the end of thermoelement 614 connected to the first part 602 and dissipated at the end of thermoelement 614 connected to the second part 604. Alternating the p-type and n-type thermoelements may be necessary to ensure that the temperature of first part 602 is less than that of second part 604 due to the current flowing from first part 602 to second part 604. Thermoelement 614 may be connected to first part 602 and second part 604 with conductive solder materials. In some embodiments, these solders include, but are not limited to, tin solders, bismuth solders and lead solders.

Cooling power of TED 600 is inversely proportional to its transport length (marked L in FIG. 7A). As explained previously, typically, conventional thermoelements have a thickness (or transport length)≥about 1 mm. Therefore, commercially available TEDs formed from conventional thermoelements have a high transport length (>1 mm), and a low cooling power (<60 Watts). Increasing the cooling power by decreasing the transport length of conventional thermoelements is difficult because of the practical difficulties in manufacturing thermoelectric material wafers below a thickness of about 1 mm, and for other reasons. TEDs used in applications such as refrigerators and water coolers may require a cooling power of at least 200 Watts. Therefore, commercially available TEDs may not be suitable for such applications. To reduce the transport length, and increase its cooling power, TED 600 is divided or replicated into two TEDs with a reduced transport length, and hence, increased cooling power. In FIG. 7A, the dashed line 616 indicates a location of the thermoelements 614 between first part 602 and second part 604. In some embodiments, dashed line 616 may be the midpoint of the thermoelements 614. TED 600 is may be divided along dashed line 616 to produce a first bifurcated part 702 and a second bifurcated part 704.

FIG. 7B illustrates a side view of the bifurcated parts of TED 600. Any method may be used to divide TED 600 into the first bifurcated part 702 and the second bifurcated part 704. In some embodiments, TED 600 may be divided using a cutting process. Cutting TED 600 separates thermoelement 614 into a first thermoelement 706 and a second thermoelement 708. In some embodiments, TED 600 may be cut along a plane substantially parallel to the first part 602 and/or the second part 604. In some embodiments, TED 600 may be cut using a fine wire saw to achieve a precise cutting. However, other cutting methods (for example, electric discharge machining, water jet machining, etc.) may also be used to cut TED 600. A number of TEDs 600 may be cut simultaneously to achieve higher efficiency.

As illustrated in FIG. 7C, after cutting, the first bifurcated part 702 and the second bifurcated part 704 are deposited (for example, by sputtering) with a layer of barrier material such as TiW or Ni. The first and the second bifurcated parts 702, 704 are arranged such that the top surfaces of the first and second thermoelements 706, 708 are deposited with the barrier material. In some embodiments, stencils 802 and 804 with openings aligned with the top surfaces of the first and second thermoelements 706, 708 are used as a mask to minimize deposition of the barrier material on other parts of the first and the second bifurcated parts 702, 704. In FIG. 7C, arrows 806 and 808 depict the deposition of barrier material by sputtering.

After depositing the barrier material atop the first and second thermoelements 706, 708, the first and second bifurcated parts 702, 704 are attached to a first ceramic substrate 902 and a second ceramic substrate 904, respectively, to create two replicated TEDs. Any attachment method may be used to attach these parts together. In some embodiments, a solder may be used to attach the parts. FIG. 7D illustrates a side view of the bifurcated parts 702, 704 during soldering. The first and second thermoelectric substrates 902, 904 may include ceramic substrates 906, 910 (for example, aluminum nitride) with patterned metallic interconnects 908, 912 thereon.

Lumps of solder 920, 930 may be deposited (or placed) on the metallic interconnects 908 and 912 of the first and second thermoelectric substrates 902, 904. Any known technique may be used to deposit the solder 920, 930 on these substrates. In some embodiments, the solder 920, 930 may be squeegeed or screen printed on the metallic interconnects. A stencil having a predetermined pattern of openings may first be placed over the substrates 902, 904 with their openings aligned with the metallic interconnects 908, 912. A slurry of the desired solder may be placed on the stencil and squeegeed across its openings to deposit the solder 920, 930 on the metallic interconnects 908, 912.

The first and second thermoelectric substrates 902, 904 are placed on the first and second bifurcated parts 702, 704 such that the solder 920, 930 rests atop (or is adjacent to) the first and second thermoelements 706, 708 of the bifurcated parts 702, 704. The parts may be then be heated (for example, in an oven, hot plate, etc.) to reflow the solder and create a solder joint. As indicated in FIG. 7E, the transport length of replicated TEDs 1002, 1004 is half that of TED 600 of FIG. 7A. Therefore, the cooling power of TEDs 1002 and 1004 will be twice that of TED 600.

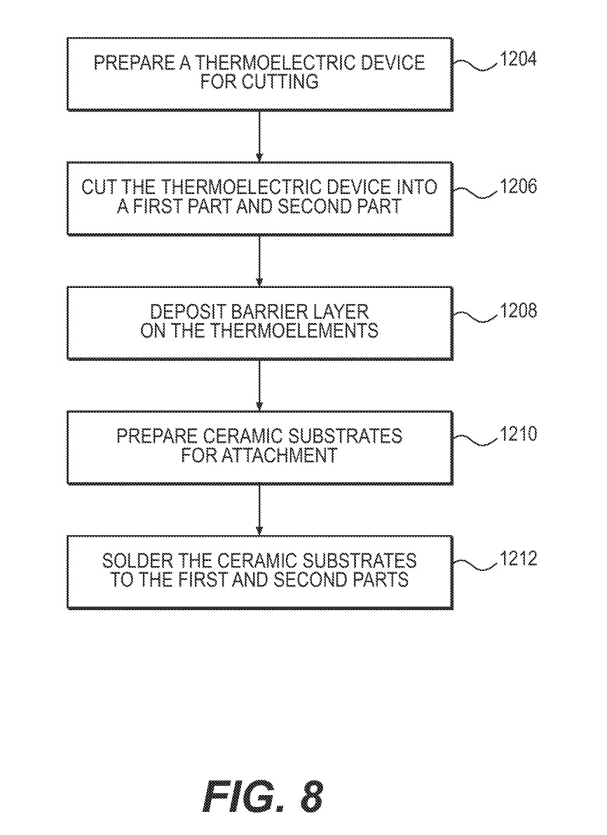

FIG. 8 illustrates a flow chart describing an exemplary method for replicating TED 600. In the description below, reference will also be made to FIGS. 7A-7E. At step 1204, a starting TED (such as TED 600 of FIG. 7A having, for example, a cooling power of about 60 Watts) is identified, selected, and/or prepared for replication. At step 1206, this starting TED is divided (for example, cut along a plane substantially parallel to the first part 602 of TED 600) into two parts to create a first bifurcated part 702 and a second bifurcated part 704 (see FIG. 7B). The division process separates or bifurcates thermoelement 614 into a first thermoelement 706 and a second thermoelement 708. After division, the bifurcated parts are cleaned to remove debris from the first and second thermoelements 706, 708. At step 1208, the top surface of each of the first and second thermoelements 706, 708 is sputter deposited (or deposited using another suitable process) with a layer of barrier material (see FIG. 7C).

At step 1210, a first thermoelectric substrate 902 and a second thermoelectric substrate 904 may be selected and/or prepared (see FIG. 7D). The first and second thermoelectric substrates 902, 904 may include solder 920, 930 deposited on the metallic interconnects 908 and 912 of these substrates. At step 1212, the first ceramic substrate is soldered to the first bifurcated part, and the second ceramic substrate is soldered to the second bifurcated part to create replicated TEDs 1002, 1004 (see FIG. 7E). Since these replicated TEDs 1002, 1004 have half the transport length of TED 600 of FIG. 7A, they have twice the cooling power of TED 600.

Although FIGS. 7A-7E and FIG. 8 only describe a method for dividing and replicating a TED once, this is not a limitation. Replicated TEDs 1002 and 1004 can be further divided and replicated using a similar procedure. By successive divisions and replications, commercially available TEDs with a transport length of about one millimeter can be replicated to create TEDs with a transport length of less than or equal to 0.03 mm to provide a significant increase in cooling power.

Table II below compares the estimated performance characteristics of a replicated thermoelectric device (for example, TED 1002 or 1004) with TED 600.

TABLE 1
Performance comparison of a replicated TED with a conventional TED.

| | | | Cost ($) | | |
|---|---|---|---|---|---|
| | | | α = $4.00, | Cost of | Watts/$ |
| Number of | Qₘₐₓ | J_{qmax} | β = $1.00, | Equivalent | for |
| Replications | (W) | (W/cm²) | γ = $0.50 | Module ($) | TECs |
| 0 | 60 | 3.75 | 5.00 | 5.00 | 12 |
| 1 | 120 | 7.50 | 3.25 | 10.00 | 37 |
| 2 | 240 | 15 | 2.37 | 20.00 | 101 |

The first row of Table I indicates the characteristics that have been considered for comparing the performance of a replicated thermoelectric devices with TED 600. The first column (labeled “Number of Replications”) indicates the number of times TED 600 of FIG. 7A has been replicated. The row with zero replication indicates the characteristics of TED 600. The row with one replication indicates the estimated characteristics of a TED made by replicating TED 600 once (that is TEDs 1002, 1004). The row with two replications indicates the characteristics of a TED made by replicating TED 600 twice.

Qₘₐₓ indicates the maximum cooling power of the TEDs in Watts (W). J_{qmax} indicates the maximum cooling density of the TEDs in Watts per centimeter square (W/cm²). Cost ($) indicates the cost of one TED in US dollars. In Table II, the cost of replicated TEDs has been determined on the basis of three parameters α, β, and γ, wherein:

α is the cost of one thermoelement;

β is the cost of two ceramic substrates; and

γ is the cost of replicating a TED once. This includes the cost of processes such as cutting, sputtering, soldering, etc.

In an embodiment of the present invention, α is $4, β is $1, and γ is $0.5.

Cost of TED 600 is c, where

c=α+β

Cost of a TED replicated once is c′, where

α¹=(c+β+γ)/2

In other words,

α¹=(α+2β+γ)/2

Therefore, cost of a TED manufactured by replicating TED 600 once, is $3.25 and the cost of a TED manufactured by replicating TED 600 twice is $2.37.

Cost of Equivalent Module ($) refers to the cost (in US dollars) of a conventional TED of a given cooling power. For example, cost of a conventional TED of a cooling power of 120 Watts is $10 as compared to $3.25, which is the cost of a TED replicated once and having a cooling power of 120 Watts.

W/$ for TEDs refers to the cooling power per unit cost of the thermoelectric cooling devices. It can be observed from Table II that replicating TEDs in accordance with the present invention leads to increased cooling power per unit cost.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention.

We claim:

1. A method of creating a replicated thermoelectric device from a starting thermoelectric device, wherein the starting thermoelectric device includes a plurality of thermoelements attached between opposing surfaces of a first substrate and a second substrate such that the starting thermoelectric device is configured to extract heat from the first substrate and discharge the extracted heat at the second substrate when a current flows through the plurality of thermoelements, the method comprising:
cutting through each thermoelement of the plurality of thermoelements along a plane positioned between the opposing surfaces of the first substrate and the second substrate and passing through each thermoelement of the plurality of thermoelements to create (i) a first part with a first portion of the plurality of thermoelements and (ii) a second part with a second portion of the plurality of thermoelements; and
attaching a third substrate to the first part to create a replicated thermoelectric device, wherein the third substrate is attached such that the first portion of the plurality of thermoelements is positioned between the first substrate and the third substrate, wherein the replicated thermoelectric device is configured to extract heat from the first substrate and discharge the extracted heat at the third substrate when a current flows through the first portion of the plurality of thermoelements.

2. The method of claim 1, wherein the replicated thermoelectric device is a first replicated thermoelectric device, and the method further includes attaching a fourth substrate to the second part to create a second replicated thermoelectric device, wherein the fourth substrate is attached such that the second portion of the plurality of thermoelements is positioned between the second substrate and the fourth substrate.

3. The method of claim 1, wherein attaching the third substrate to the first part includes soldering the third substrate to a top surface of the first portion of the plurality of thermoelements.

4. The method of claim 1, further including depositing a barrier material on a top surface of the first portion of the plurality of thermoelements prior to attaching the third substrate.

5. The method of claim 1, wherein attaching the third substrate includes attaching the third substrate such that the first portion of the plurality of thermoelements are connected electrically in series.

6. The method of claim 1, wherein cutting through each thermoelement includes cutting each thermoelement along a plane substantially parallel to the first substrate.

7. The method of claim 1, wherein cutting through each thermoelement includes cutting each thermoelement along a plane positioned substantially midway between the first substrate and the second substrate.

8. The method of claim 1, wherein the first substrate and the second substrate are Aluminum Nitride substrates with metallic interconnects thereon.

9. The method of claim 8, wherein the plurality of thermoelements are connected between the metallic interconnects of the first and second substrates.

10. The method of claim 1, wherein the third substrate is an Aluminum Nitride substrate with metallic interconnects thereon, and wherein attaching the third substrate to the first part includes attaching the first portion of the plurality of thermoelements to metallic interconnects of the third substrate

11. A method of creating a replicated thermoelectric device from a single thermoelectric device, the single thermoelectric device including a plurality of thermoelements attached between opposing surfaces of a first substrate and a second substrate such that the single thermoelectric device is configured to produce electrical energy when subjected to a temperature gradient between the first substrate and the second substrate, the method comprising:
dividing the single thermoelectric device along a plane extending between the opposing surfaces of the first substrate and the second substrate to cut through each thermoelement of the plurality of thermoelements and form (a) a first part with a first portion of the plurality of thermoelements, and (b) a second part with a second portion of the plurality of thermoelements; and
attaching a third substrate to the first part to create a replicated thermoelectric device, wherein the third substrate is attached such that the first portion of the plurality of thermoelements is positioned between the first substrate and the third substrate, wherein the replicated thermoelectric device is configured to produce electrical energy when subjected to a temperature gradient between the first substrate and the third substrate.

12. The method of claim 11, wherein the dividing includes cutting through each thermoelement of the plurality of thermoelements along a plane substantially parallel to the first substrate.

13. The method of claim 11, wherein the attaching includes soldering the third substrate to the first portion of the plurality of thermoelements.

14. The method of claim 11, wherein the dividing includes cutting each thermoelement of the plurality of thermoelements along substantially a midpoint between the first and the second substrates.

15. The method of claim 11, wherein the plurality of thermoelements include one or more p-type thermoelements and one or more n-type thermoelements.

16. A method of creating a replicated thermoelectric device from a starting thermoelectric device, wherein the starting thermoelectric device is one of (a) a thermoelectric cooling device configured to transfer heat from one location to another location when a current is directed through the starting thermoelectric device, or (b) a thermoelectric generator configured to generate an electric current when a temperature gradient is applied across the starting thermoelectric device, and wherein the starting thermoelectric device includes a plurality of thermoelements coupled between opposing surfaces of a first substrate and a second substrate, the method comprising:
cutting the plurality of thermoelements along a plane extending between the opposing surfaces of the first substrate and the second substrate and passing through each thermoelement of the plurality of thermoelements to create (i) a first part with a first portion of the plurality of thermoelements and (ii) a second part with a second portion of the plurality of thermoelements; and
coupling a third substrate to the first portion of the plurality of thermoelements to create a first replicated thermoelectric device, and a fourth substrate to the second portion of the plurality of thermoelements to create a second replicated thermoelectric device, wherein each of the first replicated thermoelectric device and the second replicated thermoelectric device is one of a thermoelectric cooling device or a thermoelectric generator.

17. The method of claim 16, further including depositing a barrier material on a top surface of the first portion of the plurality of thermoelements prior to coupling the third substrate.

18. The method of claim 16, wherein coupling the third substrate includes coupling the third substrate such that the first portion of the plurality of thermoelements are connected electrically in series.

19. The method of claim 16, wherein cutting the plurality of thermoelements includes cutting through each thermoelement of the plurality of thermoelements along a plane substantially parallel to the first substrate.

20. The method of claim 16, wherein cutting the plurality of thermoelements includes cutting through each thermoelement of the plurality of thermoelements along a plane positioned substantially midway between the opposing surfaces of the first substrate and the second substrate.
